(19) United States
(12) Patent Application Publication
(10) Pub. No.: US 2011/0017286 A1
(43) Pub. Date: Jan. 27, 2011

(54) COMPOSITE NANORODS WITH DISTINCT REGIONS

(75) Inventors: Paul A. Alivisatos, Berkeley, CA (US); Bryce Sadtler, Los Angeles, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: The Regents of the University of California, Oakland, CA (US)

(21) Appl. No.: 12/933,720

(22) PCT Filed: Mar. 23, 2009
(86) PCT No.: PCT/US09/37952

§ 371 Date: Sep. 21, 2010

Related U.S. Application Data
(60) Provisional application No. 61/039,054, filed on Mar. 24, 2008.

(51) Int. Cl. H01L 31/0352; H01L 29/06; H01L 21/34

(52) U.S. Cl. 136/255; 257/9; 438/104; 257/E29.005; 257/E31.015; 257/E31.033; 257/E21.459; 977/762; 977/948

(57) ABSTRACT

A nanorod is disclosed. It includes a linear body including three or less alternating regions including a first region and a second region, wherein the first region comprises a first material comprising a first ionic material and the second region comprises a second material comprising a second ionic material.

### CROSS-REFERENCES TO RELATED APPLICATIONS

This application is a non-provisional of and claims the benefit of the filing date of U.S. Patent Application No. 60/039,054, filed on Mar. 24, 2008, which is herein incorporated by reference in its entirety for all purposes.

This application is also related to PCT/US2008/069384, filed on Jul. 8, 2008, and U.S. Provisional Application Nos. 60/948,971, filed on Jul. 10, 2007, and 60/987,547, filed on Nov. 13, 2007, which are all incorporated by reference in their entirety for all purposes.

### STATEMENT AS TO RIGHTS TO INVENTIONS MADE UNDER FEDERALLY SPONSORED RESEARCH OR DEVELOPMENT

The invention described and claimed herein was made in part utilizing funds supplied by the U.S. Department of Energy under Contract DE-AC02-05CH11231. The government has certain rights in this invention.

### BACKGROUND OF THE INVENTION

The synthesis of nanocrystal heterostructures, having two or more components within each particle, is desirable both for creating multi-functional materials and for controlling electronic coupling between nanoscale units (Yin, Y.; Alivisatos, A. P. Nature, 437:664-670 (2005); Jun et al., J. Chemical Communications, 1203-1214 (2007); Cozzoli et al., Chemical Society Reviews, 35:1195-1208 (2006); Casavola et al., European Journal of Inorganic Chemistry, 837-854 (2008)). As the complexity of colloidal nanocrystal heterostructures increases beyond simple spherical core-shell morphologies, their electronic structure and physical properties will strongly depend on the spatial organization of the two materials within each nanocrystal. Colloidal nanocrystals possessing anisotropic shapes provide a platform for selective chemical modification based on the relative reactivities of the different crystalline facets exposed at the surface. This enables the synthesis of multi-component nanostructures through the nucleation and growth of a secondary material on specific facets of the nanocrystals (Cozzoli et al., Chemical Society Reviews, 35:1195-1208 (2006); Casavola et al., European Journal of Inorganic Chemistry, 837-854 (2008); Shi et al., Nano Letters, 6:875-881 (2006); Milliron et al., Nature, 430:190-195 2004; Mokari et al., Science, 304:1787-1790 (2004); Kudera et al., Nano Letters, 5:445-449 (2005); Shieh et al., Journal of Physical Chemistry B, 109:8538-8542 (2005); Talapin et al., Nano Letters, 7:2951-2959 (2007)). While the methodology of sequential growth has been applied to a wide range of material combinations, its drawback is that the desired heterogeneous nucleation on the existing nanocrystal surface often competes with homogenous nucleation of separate nanocrystals of the secondary material.

An alternative method for synthesizing nanocrystal heterostructures, which circumvents separate nucleation, is the transformation of a portion of the nanocrystal into a new composition or structural phase (Sun, Y.; Xia, Y., Science, 298:2176-2179 (2002); Yin et al., Science, 304:711-714 (2004); Cable, R. E.; Schaak, R. E., Journal of the American Chemical Society, 128:9588-9589 (2006); Mews et al., Journal of Physical Chemistry, 98:934-941 (1994); Dloczik, L.; Koenenkamp, R. Journal of Solid State Electrochemistry, 8:142-146 (2004); Son et al., Science, 306:1009-1012 (2004)). In ionic nanocrystals, cation exchange reactions have been used to alter the composition of the material by replacing the cations within the nanocrystal lattice with a different metal ion (Robinson et al., A. P. Science, 317:355-358 (2007); Mews et al., Journal of Physical Chemistry, 98:934-941 (1994); Dloczik, L.; Koenenkamp, R. Journal of Solid State Electrochemistry, 8:142-146 (2004); Son et al., Science, 306:1009-1012 (2004); Wark et al., Journal of the American Chemical Society, 130:9550-9555 (2008); Camargo et al., Langmuir, 23:2985-2992 (2007); Pietryga et al., Journal of the American Chemical Society, 130:4879-4885 (2008)). For example, the addition of a small molar excess of Ag⁺ cations to cadmium chalcogenide nanocrystals (CdS, CdSe, CdTe) leads to their complete conversion to the corresponding silver chalcogenide (Son et al., Science, 306:1009-1012 (2004)). Remarkably, the shape of anisotropic nanocrystals such as rods and tetrapods is preserved after cation exchange when their dimensions are greater than the reaction zone for exchange (˜4 nm), indicating that the cohesion of the crystal is maintained during the diffusion and exchange of cations. The relative rigidity of the anion sublattice enables the partial transformation of the nanocrystal to create a heterostructure where the two compounds share a common anion. Adjusting the ratio of substitutional cations to those within the nanocrystals can be used to control the relative volume fraction of the two crystals within the binary heterostructures (Robinson et al., A. P. Science, 317:355-358 (2007)). The spatial arrangement of materials within the nanocrystal will depend on a number of kinetic and thermodynamic factors such as the relative activation barriers for cation exchange to initiate at different facets of the nanocrystal and the energetic stability of interfaces as reaction fronts proceed through the nanocrystal. In the case of Ag⁺ exchange in CdS nanorods, the reorganization of Ag₂S and CdS regions via cation diffusion causes significant changes in the morphology of the heterostructures as the fraction of Ag₂S increases within each nanorod (Robinson et al., A. P. Science, 317:355-358 (2007); Demchenko et al., ACS Nano, 2:627-636 (2008)). Low amounts of Ag⁺ produce small Ag₂S regions dotting the surface of the nanocrystals, whereas greater amounts of Ag⁺ lead to alternating segments of CdS and Ag₂S along the nanorod. The large lattice strain between CdS and Ag₂S is believed to play an notable role in forming the striped pattern observed for this system. Thus, it is interesting to examine a case where the lattices of the cation exchange pair have little mismatch between them.

The use of colloidal nanocrystals in solar cell devices is a highly active area of research. Colloidal semiconductor nanocrystals are attractive materials as the active layer in solar cells as they allow solution-phase processing to be used, which may significantly lower fabrication costs. Previous solar cell devices incorporating nanocrystals have either used blends of nanocrystals with organic polymers or bilayers of two different types of semiconductor nanocrystals. In these cases, the contact between the two active components (electron-accepting and electron donating) was not well-defined and could vary with device batch. Forming well-defined and strong contact between the electron-accepting and electron-donating components of a nanocrystal-based solar cell device is desirable for increasing performance. The present inventors have produced binary nanocrystal heterostructures, which contain both electron-accepting and electron-donating regions within a single nanocrystal. In this case, the connectivity between the two materials is well-defined and can be controlled. Such a configuration has many benefits, which can lead to power conversion efficiencies closer to theoretical limits. These benefits include: more efficient charge separation, reduction in surface trap states common at the interface of two heterogeneous materials, and improved charge mobility.

Embodiments of the invention address these and other problems, individually and collectively.

### BRIEF SUMMARY OF THE INVENTION

Embodiments of the invention include the synthesis of CdS—Cu₂S nanorod heterostructures synthesized by partial Cu⁺ cation exchange. The Cu₂S regions primarily occur at one or both ends of the nanorods and appear to nucleate and grow along a single crystallographic direction. The values of CdS—Cu₂S interface formation energies provided by theoretical modeling suggest that the asymmetric CdS—Cu₂S heterostructures that are observed are produced by selective Cu₂S nucleation on the (000 1̅) CdS end facet, as this interface has a lower formation energy than the attachment of Cu₂S to the opposite (0001) end. Asymmetric CdS—Cu₂S binary nanorods are potential candidates for nanocrystal-based solar cell devices as the two materials have a type II (staggered) electronic band alignment leading to optically excited charge separation at the CdS—Cu₂S interface and the elongated rod shape is conducive to charge extraction at opposite ends of the nanostructure. Embodiments of the invention, however, are not limited to CdS—Cu₂S heterostructures.

One embodiment of the invention is directed to a composite nanorod comprising: a linear body including three or less alternating regions including a first region and a second region, wherein the first region comprises a first (ionic) material comprising a first ionic material and the second region comprises a second (ionic) material comprising a second ionic material. The first and second ionic materials may be ionic semiconducting materials.

Another embodiment of the invention is directed to a method comprising: forming a mixture comprising nanorods comprising a first (ionic) material comprising first ions, coordinating molecules, and second ions in a solvent; and forming composite nanorods in the solvent, wherein each composite nanorod comprises a linear body comprising a first region comprising the first material and a second region comprising a second (ionic) material, wherein the second material comprises the second ions, and wherein the linear body including three or less alternating regions.

Another embodiment of the invention is directed to a composite nanorod comprising: a linear body including a first region and a second region, wherein the first region comprises a first (ionic) material comprising cadmium sulfide and the second region comprises a second (ionic) material comprising copper sulfide.

Another embodiment of the invention is directed to a method comprising: forming a mixture comprising nanorods comprising a first (ionic) material comprising first ions, coordinating molecules, and second ions in a solvent; and forming composite nanorods in the solvent, wherein each composite nanorod comprises a linear body comprising a first region comprising the first material and a second region comprising a second (ionic) material, wherein the first material comprises cadmium sulfide and the second material comprises copper sulfide.

Other embodiments of the invention are directed to devices including such composite nanorods.

Some embodiments of the invention are directed to binary nanorod heterostructures, which are rod shaped nanocrystals comprising at least two semiconducting materials. The process can start with nanorods composed of a single material and uses a simple chemical transformation to convert the nanorods to the binary heterostructures. Referring to FIGS. 1(a) and 1(b), in one example, cadmium sulfide (CdS) nanorods 10, synthesized through standard procedures, were chemically converted to binary cadmium sulfide-copper sulfide nanorods (CdS—Cu₂S) through a partial cation exchange reaction where copper cations (Cu⁺) replace a portion of the cadmium cations (Cd²⁺) within the crystalline lattice of the nanorod. Through this technique, it is possible to systematically control the amount of CdS, which is converted to Cu₂S and thus the relative proportions of the two materials within the nanorod. Unlike other methods for forming a connection between two nanocrystals, such as the sequential growth of one nanocrystal onto another (T. Mokari et al. Science 304, 1787 (2004)), the cation exchange process ensures epitaxial attachment between the crystalline lattices of the two materials (R. D. Robinson et al. Science 317, 355 (2007)). This epitaxial attachment leads to strong coupling of the two regions. The well-defined geometry and strong coupling of the CdS and Cu₂S materials in the binary nanorods leads to efficient charge separation as evidenced by the quenching of the CdS photoluminescence after cation exchange.

These and other embodiments of the invention are described in further detail below.

### BRIEF DESCRIPTION OF THE DRAWINGS

FIGS. 1(a) and 1(b) show a schematic of the cation exchange process for making CdS—Cu₂S nanorods.

FIG. 2 shows a schematic of aligned Cu₂S—CdS nanorods in a solar cell device.

FIG. 3 shows X-ray diffraction (XRD) patterns of the CdS nanorods before and after the addition of increasing amounts of Cu⁺ cations.

FIGS. 4(a)-4(d) show bright field transmission electron microscopy (TEM) images before and after complete Cu⁺ cation exchange, along with size distributions of the nanorods.

FIGS. 5(a)-5(d) show composite energy-filtered images of the CdS and Cu₂S portions of the binary nanorods, where the ends of the nanorods have been converted to Cu₂S. A high-resolution TEM image of a CdS—Cu₂S nanorod heterostructure is also shown

FIGS. 6(a)-6(e) show Cu-EFTEM images for three CdS—Cu₂S binary nanorod samples along with histograms of the asymmetry of the length of the Cu₂S segments and total Cu₂S length fraction within individual nanorods for each of the samples shown.

FIG. 7 shows a general schematic of the changes in morphology of the CdS—Cu₂S and CdS—Ag₂S binary nanorods as the Cu⁺/Cd²⁺ or Ag⁺/Cd²⁺ ratio increases

### DETAILED DESCRIPTION OF THE INVENTION

As used herein, the term “nanorod” is used herein to mean any linear nanostructure. An exemplary nanorod according to an embodiment of the invention may exist only as a nanorod may exists as an arm or other part of a larger two or three dimensional particle such as a tetrapod particle or other type of particle.

In some embodiments of the invention, there can be three of less alternating regions (or layers) per nanorod, and these alternating regions may be formed in a liquid medium. Adjacent alternating regions may comprise different materials. The alternating regions can comprise copper sulfide and cadmium sulfide.

The composite nanoparticles according to embodiments can be used for any suitable purpose. For example, they can be used to label biological materials, as electronic components in photovoltaic devices or light-emitting diodes, in electronic devices. etc.

The partial transformation of ionic nanocrystals through cation exchange has been used to synthesize nanocrystal heterostructures. The present inventors demonstrate that the selectivity for cation exchange to take place at specific facets of the nanocrystal plays a notable role in controlling the resulting morphology of the binary heterostructure. In the case of copper I (Cu⁺) cation exchange in cadmium sulfide (CdS) nanorods, the reaction starts preferentially at the ends of the nanorods such that copper sulfide (Cu₂S) grows inwards from either end. The epitaxial attachments of Cu₂S to the end facets of CdS nanorods minimize the interface formation energy, making these interfaces stable throughout the exchange reaction. Additionally, as the two end facets of wurtzite CdS nanorods are crystallographically nonequivalent, asymmetric heterostructures can be produced. The creation of asymmetric, elongated nanostructures, such as the CdS—Cu₂S nanorods presented herein, is desirable for novel nanocrystal-based devices, including solar cells, which utilize the separation and extraction of photo-generated charge carriers.

Cation exchange provides a facile method for systematically varying the proportion of two chemical compositions within a single nanocrystal. It has been shown that cation exchange can be used to fully (and reversibly) convert CdS (or alternatively CdSe or CdTe) nanocrystals to Cu₂S nanocrystals by a complete replacement reaction of the Cd²⁺ cations with Cu⁺ cations. The resultant material is the copper-anion analog of the starting material. The size and shape of the nanocrystal can be preserved when the nanocrystal has minimum dimensions greater than about 4 nm. The high mobility of cations in the CdS (as well as CdSe and CdTe) lattice suggests that partial cation exchange may lead to interesting patterns of segregated domains of copper chalcogenide within a cadmium chalcogenide nanorod. Thus, it is possible to convert a previously formed nanorod of a single chemical composition into a nanorod heterostructure, such as CdS—Cu₂S by partial cation exchange. The exchange reaction is selective for the end facets of the anisotropic nanorods such that the Cu₂S regions grow inwards from either end. This facet selective chemical reaction can be extended to convert CdSe and CdTe nanorods into Cu₂Se or Cu₂Te containing nanorod heterostructures.

The above-described nanorods may be formed using any suitable process. In some embodiments, before the mixture is formed, precursor nanorods may first be formed in solution. For example, the prercursor nanorods can be formed using the methods described in U.S. Pat. Nos. 6,225,198 and 6,306,736. The nanorods may be purely linear structures, or may be arms in two or three-dimensional nanostructures, such as in a nanotetrapod. Such precursor nanorods may consist only of one material (e.g., only CdS) such as one compound semiconductor material. The material in the precursor nanorods may correspond to a first material. The first materials may contain ions (e.g., Cd²⁺), which are exchanged during the composite nanorod formation process.

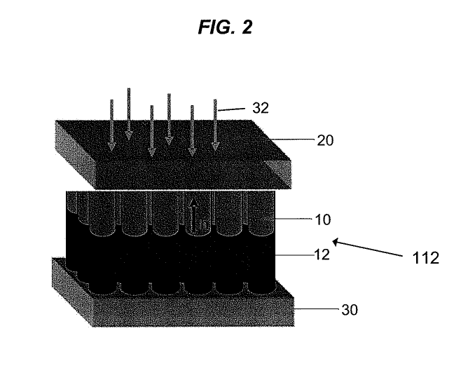

After the precursor nanorods are formed, they may remain in the solution in which they were formed. Alternatively, the precursor nanorods may be in a dry state, and may then be mixed with a solvent to form a solution. For example, to produce the aligned nanorod film shown in FIG. 2, the single component CdS nanorods can first be aligned on a suitable substrate, and then be converted to the CdS—Cu₂S composite nanorods. In either case, a first solution comprising the precursor nanorods is formed.

Once the first solution is formed, coordinating molecules and second ions may be added to the solution. The second ions (e.g., Cu⁺) may be in the form of an ionic compound (a copper salt) prior to being added to the solution. The ionic compound may be mixed with a second solvent having coordinating molecules (e.g., methanol) to form a second solution, which may be added to the first solution comprising the precursor nanorods comprising the first material (e.g., CdS). When the ionic compound is added to the first solution, the ions forming the ionic compound may dissociate in solution.

The reaction of the ionic compound (e.g., a copper salt) and nanorods (e.g., CdS nanorods) occurs at room temperature to form the composite nanorods (e.g., Cu₂S/CdS nanorods). In the formation of Cu₂S—CdS composite nanorods, second ions such as Cu⁺ ions can replace some Cd²⁺ ions in the precursor CdS nanorods. Alternatively, a suitable temperature range for performing the reaction is between −40° C. to 75° C.

Illustratively, the first solution may comprise cadmium sulfide (CdS) nanorods in toluene, and the second solution may comprise a copper salt such as tetrakis(acetonitrile)copper(I)hexafluorophosphate ([MeCN]₄Cu(I)PF₆) in methanol. It is desirable to keep this salt solution in an inert atmosphere, such as argon, to prevent oxidation of the copper salt solution. Because the reaction between the precursor nanorods and the ionic compound can be fast in some instances, lowering the temperature may slow down the reaction such that the two solutions can fully mix before the reaction occurs. Good mixing is desirable to ensure that the reaction occurs evenly (to the same extent) among the nanorods in solution (although there will always be some distribution). Otherwise, the cation exchange reaction that forms copper sulfide (Cu₂S) within the CdS nanorods by exchange of Cd²⁺ with Cu⁺ can occur before the two solutions are well-mixed, leading to different conversion fractions of the CdS nanorods in solution to Cu₂S.

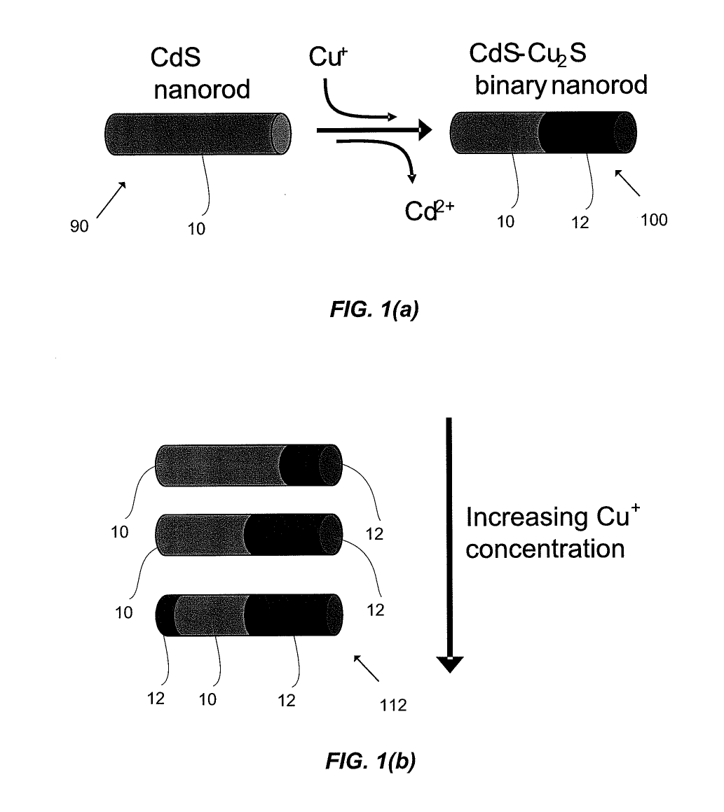

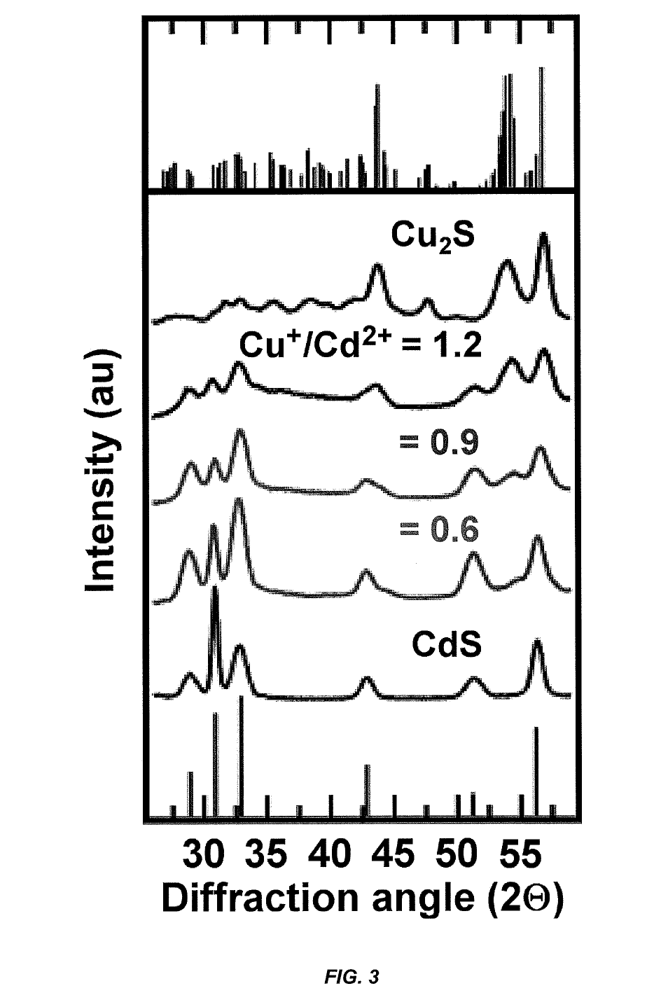

The mixture used to form the composite nanorods can have a second ion/first ion weight or molar ratio between 0 and 2 in some embodiments. For example, in the case that the second ion is Cu⁺ and the first ion is Cd²⁺ and the nanorods are CdS, increasing the Cu⁺/Cd²⁺ ratio will increase the fraction of Cu₂S within the nanorods, as shown schematically in FIG. 1b. XRD patterns shown in FIG. 3 show the progressive conversion of CdS to Cu₂S as the Cu⁺/Cd²⁺ ratio is increased. An excess of Cu⁺ ions (Cu⁺/Cd²⁺>2) will lead to complete conversion of the nanorods to Cu₂S. In other material pairs, the second ion/first ion ratio may be different to achieve a specific composition of the two materials within the nanocrystal.

Coordinating molecules added to the solution can be used to either to facilitate or hinder the ion exchange process. Molecules that preferentially solvate the second ion will inhibit the reaction, whereas molecules that preferentially solvate the first ion will promote the exchange reaction. For example, in the case that the second ion is Cu⁺ and the first ion is Cd²⁺, methanol or other alcohols facilitate the reaction by preferentially solvating Cd²⁺. However, the presence of coordinating molecules such as alkyl amines and thiols was found to inhibit the reaction by coordinating to the Cu⁺ ions in solution. As noted above, the coordinating molecules may be in a second solution comprising the second ions (e.g., Cu⁺). The second solution could optionally include polar solvents such as acetonitrile, acetone, dimethylsulfoxide (DMSO), and N,N-dimethylformamide (DMF).

The first solution including the precursor nanorods may include any suitable solvent. The solvent may comprise an organic solvent. For example, the solvent may include saturated or unsaturated cyclic (or linear) hydrocarbons alone, or in combination with other molecules. In some cases, the solvent comprises at least one of hexanes, benzene, toluene, cyclohexane, octane or decane. Other examples of suitable solvents include halogenated solvents such as chloroform or tetrachloroethylene.

Rapid stirring is desirable in some embodiments. The solution is desirably well-mixed before the reaction occurs. In the case where either the second ion, first ion, or the nanorods are sensitive to oxygen and water, the reaction can be performed in an inert atmosphere, such as argon or nitrogen. For example, the exclusion of oxygen and water is desirable to prevent oxidation of the Cu⁺ ions in solution. However, after the reaction has occurred, the nanocrystals can be exposed to air. In cases where the materials are not sensitive oxygen or water, the reaction can be performed in air.

An exemplary composite nanorod according to an embodiment of the invention may have alternating regions, which alternate axially down the linear body of a nanorod. The alternating regions may have different materials and may be in any suitable form. For example, the alternating regions may be in the form of alternating layers of different ionic compounds such as Cu₂S and CdS. The ionic compounds may include other types of materials including CdSe, ZnS, ZnSe, PbS, PbSe, HgS, FeS₂, ZnO, CuO, Cu₂O, CdTe, GaAs, InP, etc.

The rate of addition of the second ion to the nanocrystals containing the first ion can be used to control the percentage of asymmetric nanorod heterostructures produced. For example, by slowly injecting Cu⁺ ions at a constant rate of 0.15 mL/minute into a solution of CdS nanorods, the fraction of asymmetric CdS—Cu₂S nanorods is greatly increased compared to fast addition of the Cu⁺ solution. It is also possible to vary the rate of injection over time. The rate of injection of second ions can be controlled using a syringe pump or similar apparatus.

The cation exchange reaction is reversible. As an example, CdS nanorods can be partially or wholly converted to Cu₂S by Cu⁺ cation exchange by using methanol, which preferentially coordinates to Cd²⁺ over Cu⁺. These nanorods can then be partially or wholly converted back to CdS through reverse exchange using Cd²⁺ cations. In the reverse exchange, a coordinating solvent or molecule is needed which preferentially solvates Cu⁺ cations over Cd²⁺. Tributylphosphine was found to be a suitable molecule for promoting the reverse exchange to convert Cu₂S to CdS.

Although CdS and Cu₂S are described in detail herein as examples of the first material and the second material, the first and second materials may be other materials in other embodiments of the invention. Also, there may be more than two distinct materials in more than two distinct regions in a single linear body in a nanorod in other embodiments of the invention. For example, the first, second, third, etc. materials may comprise semiconductors such as compound semiconductors. Suitable compound semiconductors include Group II-VI semiconducting compounds such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe. Other suitable compound semiconductors include Group III-V semiconductors such as GaAs, GaP, GaAs—P, GaSb, InAs, InP, InSb, AlAs, AlP, and AlSb.

The first ions and the second ions may include any suitable type of ions with any suitable charge states. The first and second ions are typically metal ions. For example, in the examples below, the first ion may be Cd²⁺, while the second ion may be Cu⁺. The first ion and the second ion may have different charges or the same charge.

The second ion may be derived from a precursor compound. In some embodiments, the precursors used to may include Group II, III, IV, V, and/or VI elements. For example, in embodiments of the invention, a region with material to be formed may include a Group II-VI compound semiconductor, which can be the reaction product of at least one precursor containing a Group II metal containing precursor and at least one precursor containing a Group VI element, or a precursor containing both a Group II and a Group VI element. Thus, the second ion may be an ion of a Group II or Group VI element. In other embodiments of the invention, the region of material to be formed may include a Group III-V compound semiconductor, which can be the reaction product of at least one precursor containing a Group III element and at least one precursor containing a Group V element, or a precursor containing both a Group III and a Group V element. The second ion in this example may be an ion of a Group III or V element.

The preferred embodiments that are described below are illustrated in the context of converting a CdS nanorod into a Cu₂S—CdS composite nanorod. The skilled artisan will readily appreciate, however, that the materials and methods disclosed herein will have application for a number of other nanorod or nanostructure materials.

There is theoretically no limitation on the lengths of the composite nanorods. There can be limitations on the maximum length of CdS nanorods that one can grow (˜200 nm). In the examples presented below, the nanorods were 20-60 nm in length and each nanorod contained 0, 1, or 2 Cu₂S segments. The length of each segment can be any fraction of the length of the entire nanorod. Longer nanorods could be produced in other embodiments of the invention.

In the nanorods shown in FIGS. 1(a) and 1(b), the two materials including a first region 10 comprising a first material and a second region 12 comprising a second material are arranged linearly along the length of the nanorod 100. In FIG. 1(a), a precursor nanorod 90 comprising a region 10 comprising a first material may be exposed to copper ions. The resulting nanorod 100 only includes one first region 10 and one second region 12. In FIG. 2(a), the nanorod 112 includes a first region 10 sandwiched between second and third regions 12, 14, as the copper concentration increases. The second and third regions 12, 14 may be at terminal ends of the nanorod 104. In each example, each nanorod has three or less distinct regions.

Nanorods with three or less distinctive regions can be advantageous. For example, if a nanorod has two outer regions sandwiching an inner region of a different material, the outer regions can serve as contacts to electrodes in an electrical device. Furthermore, asymmetric nanorods containing two distinctive regions at either end according to embodiments of the invention are strong candidates for use in nanocrystal-based solar cell devices. Photoexcitation of these structures can lead to charge separation at the interface of the two regions. Each region can then be used to transport a charge of opposite sign (i.e. electron or hole) to its respective electrode.

The electronic energy levels of the semiconducting CdS and Cu₂S are in a Type II band alignment such that charge separation can occur when electrons are excited under irradiation of visible and ultraviolet light. This material pair has already been demonstrated in working solar cell device using bulk films of CdS and Cu₂S (M. A. Green, Solar Cells. Kensington, New South Wales: University of New South Wales (1998), A. L. Fahrenbruch, R. H. Bube, Fundamentals of Solar Cells. Academic Press: New York (1983)). Solar cells based on films containing layers of separate CdS and Cu₂S nanocrystals have also been produced (Y. Wu, C. Wadia, W. Ma, B. Sadtler, A. P. Alivisatos, Nano Letters 8:2551 (2008)). The electronic energy levels of conduction and valence bands in the materials can be controlled by varying the diameter of the initial cadmium sulfide nanorods due to quantum size effects. The energy level alignment can also depend on the relative proportions of CdS and Cu₂S materials within the nanorod, which can be tuned in the cation exchange process.

Nanorod based solar cells have been shown to have higher efficiency than those made with spherical nanocrystals (W. U. Huynh, J. J. Dittmer, A. P. Alivisatos, Science 295: 2425 (2002). By vertically aligning the nanorods, this efficiency could be enhanced further as it would allow for better charge transport along the nanorods to the electrodes of the device (see FIG. 2). FIG. 2 shows nanorods 114, each including a first region 10 comprising a first material and a second region 12 comprising a second material, sandwiched between a first electrode 20 and a second electrode 30. The nanorods may be substantially perpendicular to the orientations of the electrodes 20, 30. The electrodes 20, 30 may be in the form of one or more layers on a substrate (e.g., ITO or indium tin oxide) coated on a substrate) or the electrodes may be in the form of conductive substrates. Light 32 can pass to the nanorods and can be converted to electricity using the nanorods 114. The nanorods 114 can be vertically aligned on a substrate using any suitable method including external electric fields. This alignment process is compatible with existing methods for fabricating nanocrystal-based devices. Further, although a binder (e.g., a polymeric binder) is not shown in FIG. 2, a binder may be used to hold the nanorods 114 together in a layer in some embodiments of the invention.

As noted above, in embodiments of the invention, partial cation exchange can be used to synthesize nanocrystal heterostructures. Partial cation exchange is a novel route to synthesize nanocrystal heterostructures, including two materials that are epitaxially connected within an individual nanocrystal. This single-step, chemical transformation enables the systematic tuning of the composition and properties of colloidal semiconductor nanocrystals. Upon the addition of copper or silver salts to a colloidal solution of cadmium sulfide (CdS) nanorods, the spontaneous replacement of cadmium cations within the CdS lattice for copper (silver) cations occurs, while preserving the original dimensions of the nanorods. The exchange process produces crystalline regions of copper sulfide (silver sulfide) within the CdS nanorods, creating binary nanorod heterostructures. The morphology of the heterostructures depends on the cation species used and the fraction of the nanorod converted. High-resolution transmission electron microscopy of the binary nanorods shows that the crystal lattices are epitaxially connected at their interface. This well-defined contact leads to strong electronic coupling between the materials, evidenced by fluorescence spectroscopy. The absorption and emission of light of the binary nanorods can be tuned throughout the visible and near-infrared regions making these novel nano-scale architectures desirable for a variety of optoelectronic applications including near-infrared emission and solar energy conversion.

Nanorods including Ag₂S and CdS have been made. One difference between nanorods including Cu₂S and CdS is that the former focuses on the spontaneous organization of the two materials to form a periodic pattern within the nanorod. In comparison, in some embodiments, the latter focuses on the ability to make a binary nanorod where one half is one material and the other half is a different material. In the former, non-selective nucleation of the Ag₂S material leads to the formation of Ag₂S regions throughout the nanorod. In the latter case, the selective nucleation of Cu₂S at one end of the nanorod leads to an asymmetric structure.

The chemical process for making the two different structures can be similar, with the difference between the two being whether silver ions, Ag⁺, or copper ions, Cu⁺, are added to the solution of cadmium sulfide, CdS, nanorods. However, the resulting nanorod heterostructures are notably different. In the former case, the Ag₂S regions are very mobile within a CdS nanorod. The two materials organize to form alternating regions of CdS and Ag₂S along the nanorod with a defined periodicity. The materials “self-assemble” in the rod. In the former example, a simple process of cation exchange can be used to make a more complex nanocrystal that is normally achieved through multiple deposition steps. However in the latter case, the Cu₂S forms on just the ends of the CdS nanorods through selective exchange of these facets and works its way towards the middle. There is no reorganization of the Cu₂S regions. In the latter example, it is possible to make a binary nanorod heterostructure, which contains two epitxially connected materials.

Most microscale electronic devices use a heterostructure of two semiconductor materials with an epitaxial interface between them (an epitaxial interface normally leads to good electronic coupling or communication between the two materials). CdS—Cu₂S nanorods can satisfy this requirement. Having this asymmetry, where one end of the nanorod is one material and the other is a different material, makes it very potentially useful for nano-scale devices.

Another aspect is the applications of the two types of nanorods, CdS—Ag₂S and CdS—Cu₂S nanorods. Both have potential uses in solar cells, but for very different reasons (i.e. the two materials would use different processes to collect solar energy and turn it into electrical energy). In the latter case, the absorption of visible photons from the sun will create an electron-hole pairs (negative charge-positive charge pair) within CdS—Cu₂S nanorods. The relative alignment of the electronic levels of these two materials allows for charge separation to occur at their interface and for the CdS to transport the electron (negative charge) and the Cu₂S material to transport the positive charge. The extraction of these charges at opposite electrodes can be used to generate a current. In the former case, the periodic arrangement of CdS and Ag₂S materials creates a linear array of Ag₂S quantum dots separated by confining regions of CdS. Such structures are of interest for colloidal quantum dot solar cells, where the sparse density of electronic states within a dot may lead to multiple exciton generation.

### EXAMPLES

I. Synthesis of CdS nanorods. Colloidal CdS nanorods were synthesized using standard techniques developed for cadmium chalcogenide nanorods (Peng, Z. A.; Peng, X. Journal of the American Chemical Society, 124:3343-3353 (2002)). The reactions were performed under air-free conditions and the CdS nanocrystals were stored in an argon-filled glove box.

II. Cation exchange of CdS nanorods. Cu⁺ cation exchange was used to convert CdS nanorods into CdS—Cu₂S binary nanorods and Cu₂S nanorods. The reactions were performed inside an argon-filled glove box at room temperature. The extent of conversion depends on the Cu⁺/Cd²⁺ ratio, where an excess of Cu⁺ ions (Cu⁺/Cd²⁺>2 as two Cu⁺ ions replace one Cd²⁺ ion for charge balance) leads to full conversion to Cu₂S. The molar concentration of Cd²⁺ ions for each CdS nanorod solution was determined by inductively coupled plasma atomic emission spectroscopy (ICP-AES) of acid-digested samples. Typical molar extinction coefficients for Cd²⁺ within the CdS nanorod solutions were 3×10⁶ mole/cm² at 300 nm measured by visible absorption spectroscopy. The amount of Cd²⁺ in the CdS nanorod solution in each reaction was between 1×10⁻⁶ to 1×10⁻⁵ moles. The salt, tetrakis(acetonitrile)copper(I) hexafluorophosphate ([MeCN]₄Cu(I)PF₆), was used in the reactions as the weak binding affinity of the anion makes the salt readily soluble in methanol such that the Cu⁺ solution is miscible with the colloidal solution of nanorods dispersed in toluene. In a typical reaction, 12 mg of [MeCN]₄Cu(I)PF₆ was dissolved in 2.5 mL of methanol (MeOH). This solution was used for full conversion or was further diluted five or ten-fold for partial conversion. For full conversion, the [MeCN]₄Cu(I)PF₆ solution (˜0.6 to 1 mL) was added to a stirring solution of CdS nanorods in toluene (˜2 mL). For partial conversion a concentrated solution of CdS nanorods in toluene (˜50-500 μL) was added to a stirring [MeCN]₄Cu(I)PF₆ solution (˜0.1-1 mL) diluted in toluene (˜2 mL). The color of the nanocrystal solution changes rapidly (<1 second) from yellow to golden brown after mixing of the Cu⁺ and CdS solutions, and the nanorods were washed by the addition of MeOH followed by centrifugation and removal of the supernatant. To examine the effect of slow addition of Cu⁺ ions, the [MeCN]₄Cu(I)PF₆ solution was loaded in a syringe pump and added at a rate of 0.15 mL/min via a capillary needle to a stirring solution of CdS nanorods in toluene.

Further details regarding suitable processing conditions used to synthesize CdS—Cu₂S binary nanorods and Cu₂S nanorods by Cu⁺ cation exchange of CdS nanorods can be found in the Table below.

| | | [Cu⁺] (moles) in | | |
|---|---|---|---|---|
| | | methanol (mL) and | [Cd²⁺] in | |
| Cu₂S Sample # | Cu⁺/Cd²⁺ | toluene (mL) | toluene | Method of mixing |
| 1 | 0.51 | 9.8 × 10⁻⁷ moles | 1.94 × 10⁻⁶ moles | CdS soln. added |
| | | Cu⁺ in 0.37 mL | Cd²⁺ in 0.17 mL | to stirring Cu⁺ |
| | | MeOH and 2 mL | toluene | solution |
| | | toluene | | |
| 2 | 0.56 | 4.9 × 10⁻⁷ mol Cu⁺ | 8.8 × 10⁻⁷ mol | CdS soln. added |
| | | in 0.4 mL MeOH + | Cd²⁺ in 0.28 mL | to stirring Cu⁺ |
| | | 1.8 mL toluene | toluene | solution |
| 3 | 0.33 | 4.7 × 10⁻⁷ mol Cu⁺ | 1.4 × 10⁻⁶ mol | Cu⁺ soln. injected |
| | | in 0.72 mL MeOH | Cd²⁺ in 3.1 mL | via syringe pump |
| | | | toluene | at 0.015 mL/min |
| | | | | to CdS solution |
| 4 | 0.6 | 4.4 × 10⁻⁶ mol Cu⁺ | 7.3 × 10⁻⁶ mol | CdS soln. added |
| | | in 0.8 mL MeOH + | Cd²⁺ in 0.425 mL | to stirring Cu⁺ |
| | | 5 mL toluene | toluene | solution |
| 5 | 0.9 | 7.7 × 10⁻⁶ mol Cu⁺ | 8.6 × 10⁻⁶ mol | CdS soln. added |
| | | in 0.61 mL MeOH + | Cd²⁺ in 0.50 mL | to stirring Cu⁺ |
| | | 5 mL toluene | toluene | solution |
| 6 | 1.2 | 1.0 × 10⁻⁵ mol Cu⁺ | 8.6 × 10⁻⁶ mol | CdS soln. added |
| | | in 0.81 mL MeOH + | Cd²⁺ in 0.50 mL | to stirring Cu⁺ |
| | | 5 mL toluene | toluene | solution |
| 7 | 8.3 | 2.6 × 10⁻⁵ mol Cu⁺ | 3.1 × 10⁻⁶ mol | Cu⁺ soln. added to |
| | | in 1.0 mL MeOH | Cd²⁺ in 3 mL | stirring CdS |
| | | | toluene | solution |
| 8 | 10 | 9.5 × 10⁻⁶ mol Cu⁺ | 9.5 × 10⁻⁷ mol | Cu⁺ soln. rapidly |
| | | in 0.7 mL MeOH | Cd²⁺ in 2 mL | added to stirring |
| | | | toluene | CdS solution |

III. Characterization. Bright field TEM images were obtained using a Tecnai G2 S-Twin electron microscope operating at 200 kV. TEM samples were prepared by placing a drop of the nanocrystal solution onto a carbon-coated copper grid in ambient atmosphere. The elemental distribution of the nanocrystals was characterized by energy-filtered transmission electron microscopy (EFTEM). The EFTEM experiments were performed using a Philips CM200 microscope or a monochromated F20 UT Tecnai microscope. Both microscopes were equipped with a field emission gun, an electron energy loss spectrometer and a Gatan Image Filter (GIF) and were operated at 200 kV. The elemental maps were obtained by using the three-window method (Brydson, R., Electron Energy Loss Spectroscopy; BIOS Scientific: Oxford, (2001)). The Cd M-edge (404 eV) and Cu L-edge (931 eV) were used to make the color composite images. The color composites of Cd and Cu-EFTEM images were made using Image-Pro Plus software. The Cu M-edge (120 eV, minor) was used for the Cu energy-filtered images.

Statistics for the length and diameter of the initial CdS nanorods and fully converted Cu₂S nanorods were gathered from bright field TEM images using Image-Pro Plus software, and at least 150 measurements were made for each sample. Statistics for the segment lengths of the CdS and Cu₂S regions in the binary nanorods were determined from EFTEM images by making at least 150 measurements. The degree of asymmetry for each CdS—Cu₂S binary nanorod was taken to be one minus the ratio of the length of the short Cu₂S segment over the length of the long Cu₂S segment. Using this definition, a nanorod possessing two Cu₂S segments of equal lengths has an asymmetry value of 0, and a nanorod with Cu₂S on only one side of the nanorod has an asymmetry value of 1. The length fraction of the nanorod converted to Cu₂S was measured as the ratio of the combined length of Cu₂S segments over the total length of the nanorod. Thus, a nanorod that is entirely composed of CdS will have a length conversion of 0, and a nanorod fully converted to Cu₂S will have a value of 1. The CdS—Cu₂S interfaces were grouped into three categories: flat and parallel to the nanorod cross-section, flat and at an angle to the cross-section, and multifaceted (which appear curved in low-magnification TEM images). As TEM imaging provides a two-dimensional projection of the nanorod heterostructures, the apparent angle and curvature of an interface depends on its relative orientation on the TEM substrate. Therefore, the fraction of each of these types of interfaces (measured from a population of over 200 nanorods) is approximate.

The crystal structures of the samples were determined from powder X-ray diffraction (XRD) obtained on a Bruker AXS diffractometer using Co Kα radiation (1.790 Å) and a general area detector. The instrument resolution was 0.05° in 2θ, and the acquisition time for each sample was one hour. XRD samples were prepared by dissolving the precipitated nanocrystals in a minimal amount of toluene or chloroform and using a capillary tube to drop the solution onto a glass sample plate.

IV. Ab initio calculations. Supercell geometries for CdS—Cu₂S epitaxial attachments were studied using the Vienna ab-initio simulation package (VASP), a density functional theory (DFT) code using planewaves and pseudopotentials (Kresse, G.; Furthmuller, J. Computational Materials Science, 6:15-50 (1996); Kresse, G.; Furthmuller, J. Physical Review, 54:11169-11186 (B 1996)). The generalized gradient approximation (GGA) was used for the exchange-correlation part, along with projector augmented wave (PAW) pseudopotentials, and planewave energy cutoffs of 280 eV. The inventors used F-point only eigenenergies in the Brillouin zone as the supercells are sufficiently large to ensure weak dispersion of energy bands. All geometries were relaxed to have the forces on atoms reduced to 0.01 eV/Å or less. The lattice parameters of the relaxed cells were used in all calculations. CdS—Cu₂S interface formation energies for epitaxial attachments between different facets of the two crystals were computed analogously to our previous calculations for the CdS—Ag₂S system where the interface formation energy is defined as the ab initio total energy difference of the supercell containing the interface and its bulk constituents (Demchenko et al., ACS Nano, 2:627-636 (2008)). Total formation energies containing both chemical and elastic contributions were obtained by using the difference in energy between the supercell and natural bulk structures. To calculate the chemical energy alone, the bulk lattices were strained similar to the lattice in the supercell. The elastic contributions were computed assuming the distortions occurred in the Cu₂S or Ag₂S cell only to match to the lattice of the CdS cell. The cell thicknesses for Cu₂S were 13.5 Å for the end-on and angled attachments to CdS and 27.3 Å for the side attachment. CdS—Ag₂S interface formation energies for similar end-on connections to the CdS nanorods were previously calculated (Demchenko et al., ACS Nano, 2:627-636 (2008)), and an additional side attachment was modeled for this work. The cell thicknesses for Ag₂S were 13.7 Å in all cases.

### Results

### I. Structural Characterization of CdS—Cu₂S Binary Nanorods

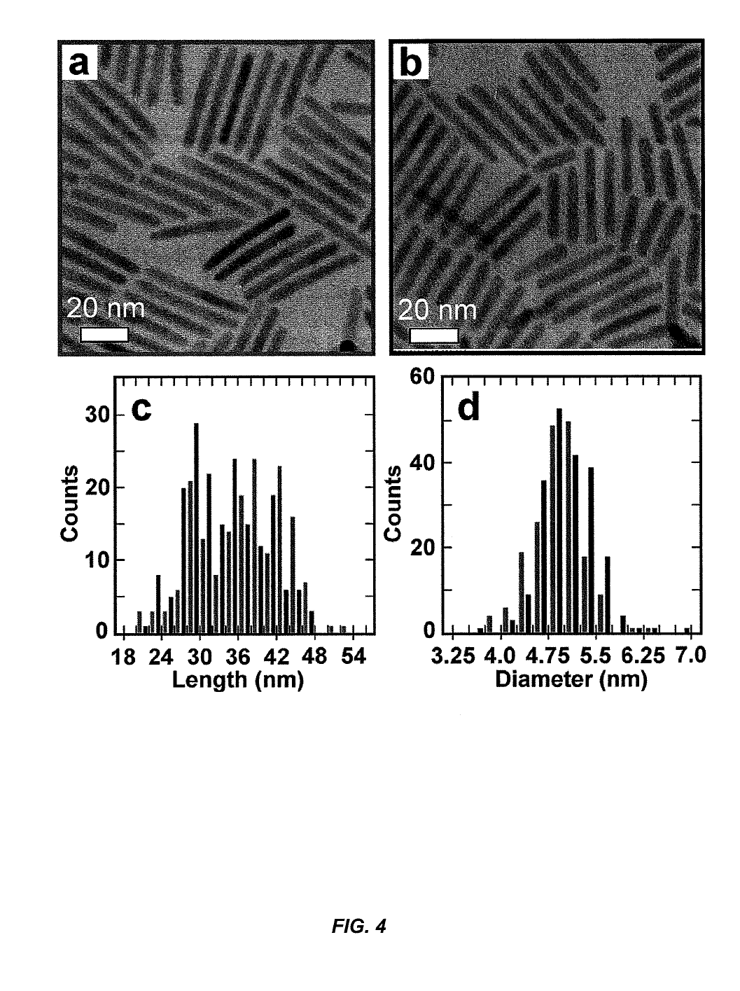

X-ray diffraction (XRD) patterns of the CdS nanorods before and after the addition of increasing amounts of Cu⁺ cations are shown in FIG. 3. The addition of excess Cu⁺ cations relative to the amount of Cd²⁺ within the wurtzite CdS nanocrystals leads to their complete transformation to the low-temperature form of chalcocite Cu₂S as measured from XRD patterns of the reactant and product nanorods (FIG. 3) (Evans, H. T., Nature Physical Science, 232:69-70 (1971)). Partially converted samples made by substoichiometric addition of Cu⁺ ions show a combination of diffraction peaks from both CdS and Cu₂S. Peaks belonging to the CdS phase disappear and peaks belonging to Cu₂S grow stronger in intensity with increasing amounts of Cu⁺ added to the solution of CdS nanorods. The bright field transmission electron microscopy (TEM) images in FIGS. 4(a)-4(d) show that after complete Cu⁺ cation exchange, the shape and size of the nanorods is preserved within the 8% contraction in lattice volume upon conversion from CdS to Cu₂S.

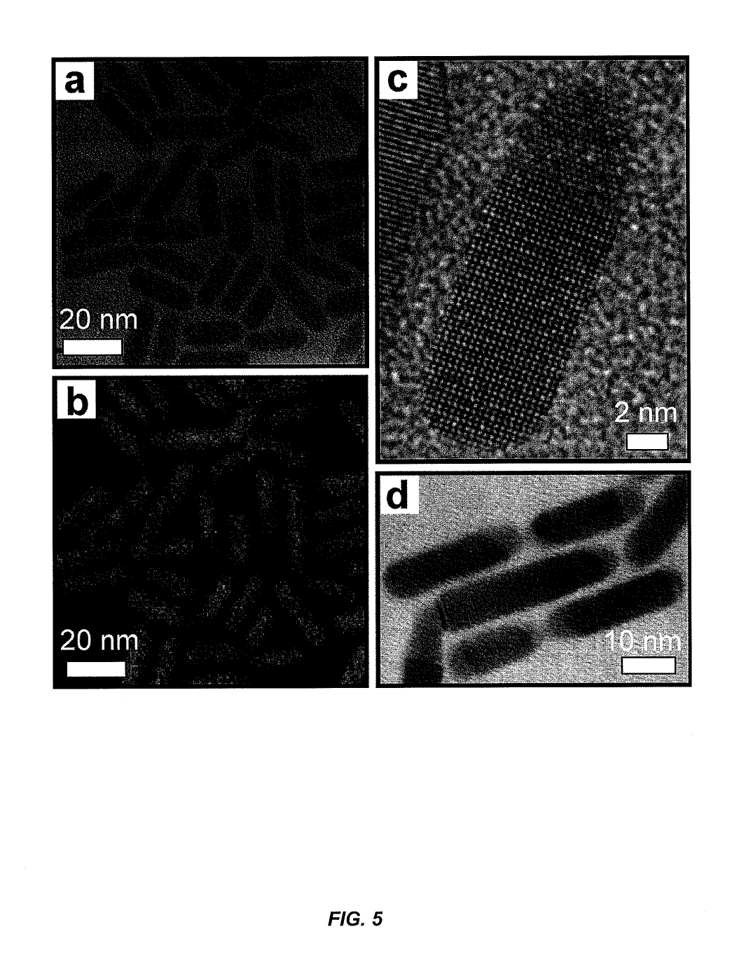

For partial Cu⁺ exchange, energy-filtered TEM (EFTEM) was used to obtain elemental mappings of the Cu- and Cd-containing regions of binary nanorods. The composite energy-filtered images in FIGS. 5(a)-5(d) clearly show the CdS and Cu₂S portions of the binary nanorods, where the ends of the nanorods have been converted to Cu₂S. The preferential conversion of the ends of the nanorods occurs for varying lengths, diameters, and aspect ratios. Observing nanorods with different fractions of conversion to Cu₂S, the EFTEM images indicate that cation exchange starts at the ends, and the Cu₂S regions grow into the nanorods upon further exchange. The only cases where Cu₂S segments existed in between regions of CdS were at sites of irregularities such as kinks along the nanorod diameter or at the zinc-blende branch-point of bipod and tripod nanocrystals (Manna et al., Journal of the American Chemical Society, 122:12700-12706 (2000)).

The high-resolution TEM (HRTEM) image of a Cu₂S—CdS heterostructure in FIG. 5(c) shows the epitaxial interface between the two materials within the nanorod (We observe electron beam induced changes to the Cu₂S crystal structure similar to previous reports in Cu₂S thin films, (A. Putnis, American Mineralogist, 62, 107-114 (1977)) which prevent analysis of the CdS—Cu₂S nanorod structure by HRTEM). The majority of interfaces are flat and parallel to the cross-section of the nanorod (parallel to the (0001) plane of CdS). However, a significant population of interfaces (up to 30% in various samples) are at an angle of up to ˜40° relative to the nanorod cross-section (see FIG. 5(d)). As the apparent angle of the interface depends on the relative orientation of the nanorod on the TEM substrate, it is likely that these interfaces occur along specific crystallographic facets of the two lattices, rather than at a continuous range of angles. Some interfaces observed by HRTEM consist of multiple facets and appear curved at lower-magnifications. Step-edges were also observed in some interfaces, which naturally arise if only a portion of cations within an atomic layer is exchanged.

While Cu⁺ cation exchange occurs at both ends of the CdS nanorods, the relative lengths of the two Cu₂S end segments within a given nanorod can vary. As the CdS wurtzite lattice lacks inversion symmetry about the c-axis, the (0001) and (000 1̅) end facets of the nanorods are crystallographically nonequivalent (Manna et al., Journal of the American Chemical Society, 122:12700-12706 (2000)). Cd atoms at a (000 1̅) surface facet expose three dangling bonds whereas Cd atoms at a (0001) surface expose only one dangling bond. Thus, the bonding arrangement of Cd atoms to the interfacial sulfur layer at the CdS—Cu₂S attachment will be different at opposite ends of the nanorod. Two factors found to affect the asymmetry of the Cu₂S end segments are the shape (curvature and diameter) of the ends of the CdS nanorods and the rate of addition of the Cu⁺ ions to the CdS solutions.

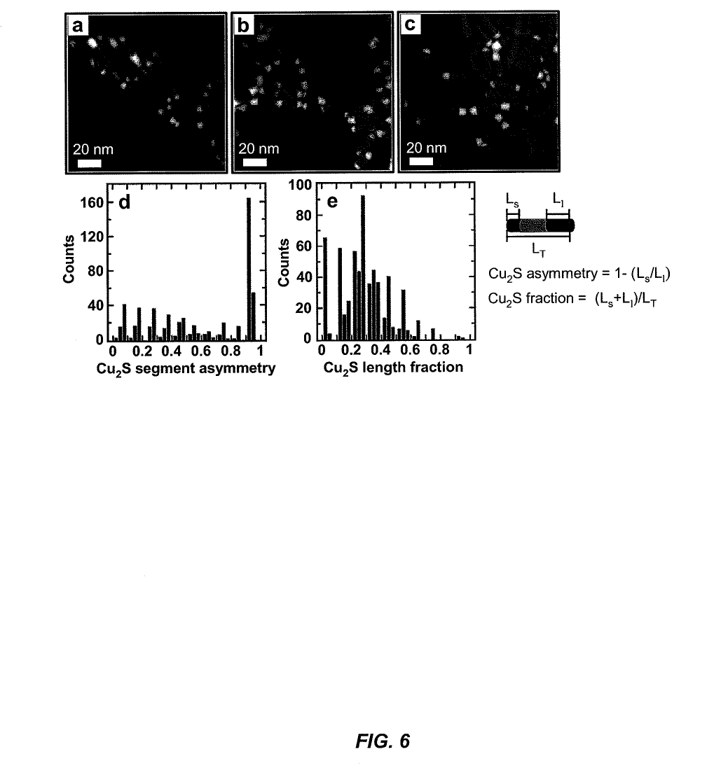

FIG. 6 shows Cu-EFTEM images for three CdS—Cu₂S binary nanorod samples along with histograms of the asymmetry of the length of the Cu₂S segments within individual nanorods for each of the samples shown. To examine the effect of the nanocrystal dimensions on the asymmetry of Cu₂S segments, partial Cu⁺ exchange was performed on nanorods of different lengths and diameters. Sample 1 shown in FIG. 6(a) used CdS nanorods with an average length of 48±7 nm (average±first standard deviation) and a diameter of 6±0.8 nm. The molar ratio of Cu⁺ cations relative to Cd²⁺ was 0.51. In this case, the Cu₂S segment lengths are symmetric, evident by the continual decrease in counts in the asymmetry histogram in FIG. 6(d) from 0 to 1. The mean asymmetry for this sample was 0.25, where the asymmetry of the two Cu₂S segments in a given binary nanorod is defined as one minus the ratio of the length of the short segment length over the length of the long segment. In sample 2 shown in FIG. 6(b), a Cu⁺/Cd²⁺ ratio of 0.56 was used to make CdS—Cu₂S heterostructures from CdS nanorods with a smaller average length but larger diameter (length=29±4 and diameter=9±0.8 nm). The reaction produced asymmetric heterostructures, as the counts in the asymmetry histogram tend to increase from 0 to 1 (mean asymmetry=0.6). As seen in FIG. 6, a significant difference between the two nanorod samples is that the ends of smaller diameter nanorods in sample 1 possess higher curvature (indicating they are composed of multiple surface facets). This appears to lead to a higher fraction of curved (multifaceted) interfaces in sample 1 (˜18%) compared to sample 2 (˜2%). On the other hand, there appears to be no correlation between the asymmetry of the Cu₂S segments and the length of the nanorods.

Sample 3 used the same initial nanorods as sample 2, but the Cu⁺ solution was added drop wise via a syringe pump to the CdS solution. Slowing the rate of addition of Cu⁺ cations to the CdS nanorods has several significant effects on the morphology of the CdS—Cu₂S heterostructures. First, it greatly enhances the asymmetry of the heterostructures leading to a majority of nanorods with Cu₂S only on one end as shown in FIG. 4c (sample 3, mean asymmetry=0.91). It also widens the distribution of the fraction exchanged among the individual nanorods within sample 3 (see FIG. 6(e)). Thus, the disparity of Cu₂S segment sizes both within individual nanorods and among the different nanorods in a sample increases from sample 1 to 2 to 3. Finally, sample 3 has fewer nanorods with interfaces that are at an angle to the cross-section of the nanorod (˜15% for sample 3 versus ˜30% for sample 2). Thus, the slow addition of Cu⁺ cations appears to increase the selectivity for nucleation of one CdS—Cu₂S interface per nanorod that is parallel to the nanorod cross-section.

### Further Discussion

### I. Comparison of Cu⁺ and Ag⁺ Cation Exchange

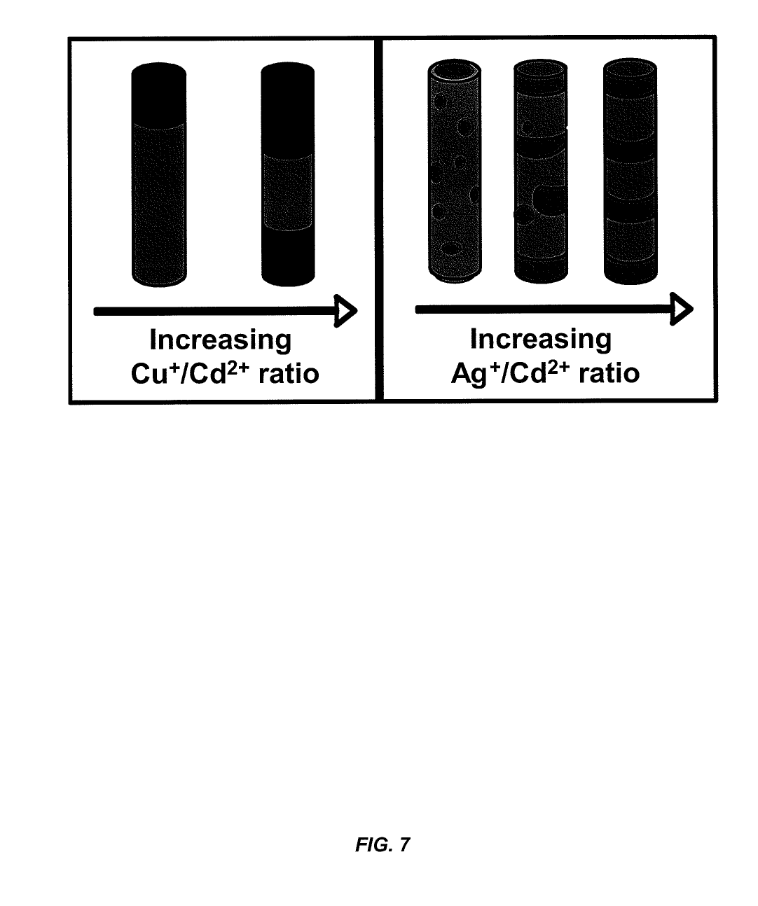

The heterostructure morphologies for different conversion fractions of the CdS nanorods to Cu₂S or Ag₂S aid in elucidating the movement of the reaction fronts during cation exchange within the nanocrystals (Demchenko et al., ACS Nano, 2:627-636 (2008)). FIG. 7 provides a general schematic of the changes in morphology of the CdS—Cu₂S and CdS—Ag₂S binary nanorods as the Cu⁺/Cd²⁺ or Ag⁺/Cd²⁺ ratio increases (for partial exchange the cation ratio is between 0 and 2). A difference between the two systems is that the Cu₂S segments are found primarily at the ends of the CdS nanorods at all stages of the exchange reaction, whereas the Ag₂S regions begin randomly distributed and become fewer in number as they grow into the nanorod. Secondly, while the multiple Ag₂S segments within a CdS nanorod are relatively uniform in size once they span the diameter of the nanorod (Robinson et al., A. P. Science, 317:355-358 (2007)), the two Cu₂S segments can have significantly different lengths. One can rationalize the observed differences in morphology through the values of the chemical and elastic contributions to the CdS—Cu₂S and CdS—Ag₂S interface formation energies.

In the CdS—Cu₂S system, where the elastic contributions to the interface formation energies are small, the relative values of the chemical formation energies determine the stability of the different CdS—Cu₂S attachments. The end-on Cu₂S attachments, parallel to the nanorod cross-section, possess the lowest chemical formation energies and are the interfaces observed most often by TEM in the heterostructures. The angled attachment connecting the basal facets of the monoclinic Cu₂S lattice to CdS has both a higher chemical formation energy per interfacial unit and produces a greater interfacial area. Correspondingly, angled interfaces occur at a significantly lower frequency, particularly in the case where the Cu⁺ ions are slowly added to the CdS solution. Finally, growth of Cu₂S on the sides of the CdS nanorods is rarely observed, which correlates with the calculated chemical formation energy that is approximately seven times greater than that of end-on connection to the (000 1̅) CdS facet. The initial nucleation of CdS—Cu₂S interfaces at the ends of the nanorods is a low-energy configuration that is maintained as the exchange front moves along the length of the nanorod. Thus, the basic morphology of the nanorods possessing Cu₂S segments at one or both ends is the same for different conversion fractions. As discussed in the next section, the asymmetry of Cu₂S segment lengths is attributed to the difference in chemical formation energies for the connection of Cu₂S to opposite ends of the nanorods.

The present inventors previously reported that when relatively low amounts of Ag⁺ are added to CdS nanorods (Ag⁺/Cd2⁺<0.5), small Ag₂S regions are found dispersed randomly over the surface of the nanocrystals (Robinson et al., A. P. Science, 317:355-358 (2007); Demchenko et al., ACS Nano, 2:627-636 (2008)). At higher conversion fractions of Ag⁺ exchange (0.5<Ag⁺/Cd2⁺<0.9), the Ag₂S regions coalesce such that they form segments that span the diameter of the nanorod and possess flat interfaces parallel to the nanorod cross-section. The negative chemical formation energies for each of the CdS—Ag₂S attachments favor the creation of Cd—S—Ag interfacial bonds on both the ends and sides of the CdS nanorods, leading to non-selective nucleation. However, as the Ag₂S regions grow into the nanorods, the elastic strain becomes a more notable contribution to the total formation energy, driving ripening of the Ag₂S regions to reduce the interfacial area. When the Ag₂S regions grow to span the diameter of the nanorod, the interfaces parallel to the length of the nanorod disappear, which possess the greatest elastic energy. At this point the ripening process becomes kinetically hindered, as further exchange of cations between the flat interfaces of the Ag₂S and CdS segments would increase the interfacial area until two like segments fully merge. While full phase segregation of the CdS and Ag₂S regions to opposite ends of the nanorod would produce to the lowest energy structure, the Ag₂S segments are stabilized by the large interfacial strain leading to a repulsive elastic interaction between like segments that decreases with increasing separation between them (Robinson et al., A. P. Science, 317:355-358 (2007); Demchenko et al., ACS Nano, 2:627-636 (2008)). Both the size and the spacing of the Ag₂S segments tend to be uniform as this minimizes the repulsive elastic interaction. Thus, non-selective nucleation followed by partial phase-segregation leads to a metastable configuration consisting of alternating CdS and Ag₂S segments. This is very different from the CdS—Cu₂S case, where once the Cu₂S regions nucleate at the ends of the nanorods, they grow until they meet in the middle.

### II. Asymmetry of Cu⁺ Cation Exchange

The relative activation barriers for nucleation at each end of the nanorod control the asymmetry of the Cu₂S segments. In principle, disparate rates of diffusion of cations in opposite directions along the nanorod could also contribute to asymmetric growth. However, previous kinetic studies of cation exchange suggest that interface nucleation provides the main kinetic barrier for transformation of the nanocrystal (Chan et al., Journal of Physical Chemisty A, 111:12210-12215 (2007)). The chemical formation energy for the Cu₂S attachment to the CdS (000 1̅) facet (I₁) is lower by ˜0.18 eV per Cd—Cu—S unit compared to attachment to the (0001) facet (I₂). Moreover, the (000 1̅) end facet of the CdS nanocrystal is believed to be the least stable surface of the nanorod as Cd-termination leads to three dangling bonds per atom, making full passivation difficult without significant surface reconstruction (Manna, L.; Wang, L. W.; Cingolani, R.; Alivisatos, A. P. Journal of Physical Chemisty B 109: 6183-6192 (2005). Therefore, the connection of orthorhombic Cu₂S to the (000 1̅) end of the nanorods produces the thermodynamically most stable configuration as it both removes a high-energy surface and creates the lowest energy interface. This suggests that the asymmetric CdS—Cu₂S nanorods are produced by selective nucleation of Cu₂S at the (000 1̅) end of the nanorod

The increased asymmetry of Cu₂S segments in sample 2 over sample 1 as shown in FIG. 6 is attributed to the larger diameter and flatter ends of the initial CdS nanorods used to produce sample 2. The shape of the CdS nanorods is kinetically-determined during their growth by the relative rates of monomer addition along different crystallographic directions of the particle (Manna et al., Journal of the American Chemical Society, 122:12700-12706 (2000); Peng, Z. A.; Peng, X., Journal of the American Chemical Society, 123:1389-1395 (2001)). Under the non-equilibrium growth conditions used to produce highly anisotropic nanocrystals, the (000 1̅) and (0001) ends of the nanorods are partially replaced by the more stable {10 1̅1} type facets leading to pencil or arrow-shaped nanorods (Manna et al., Journal of the American Chemical Society, 122:12700-12706 (2000)). The epitaxy of the nucleating interface during cation exchange will depend on the surface area of the different crystalline facets exposed. The binary nanorods in sample 1 (FIG. 6a) in which the initial nanorods ends have a higher curvature compared to those used to make sample 2 (FIG. 6b) also have a higher fraction of curved interfaces. Nanorods with multi-faceted (curved) end faces expose less of the (0001) and (000 1̅) surfaces, which may lower the selectivity for interface nucleation at one end. Furthermore, a larger diameter will accentuate the difference in total formation energy between I₁ and I₂. As larger diameter nanorods generally also possess flatter ends, these two parameters act in concert to increase the asymmetry of the Cu₂S segment lengths.

Maintaining a low concentration of Cu⁺ ions present in solution during the exchange reaction enhances the formation of a single interface in each binary nanorod. This can be seen as the asymmetry of Cu₂S segments greatly increases for slow (sample 3, FIG. 6(c)) versus fast (sample 2, FIG. 6(b)) addition of Cu⁺ cations to the same initial batch of CdS nanorods. In addition, the percentage of interfaces at an angle to the nanorod cross-section decreases for slow addition. However, the distribution of the fraction converted to Cu₂S among individual nanorods widens, indicating that nucleation and growth of Cu₂S become increasingly overlapped in time. This is expected as the concentration of Cu⁺ cations during the early stages of the drop-wise addition is not enough for nucleation to occur on all of the nanorods at once. Previous studies on the reaction kinetics of Ag⁺ cation exchange in CdSe nanocrystals support a mechanism where once an interface nucleates in a nanocrystal by cation exchange at the surface, the kinetic barrier for further exchange is relatively low (Chan et al., Journal of Physical Chemisty, 111:12210-12215 (A 2007)). Thus, upon slow addition of Cu⁺ ions, exchange will occur more rapidly at CdS—Cu₂S interfaces that have already formed over the creation of new interfaces, widening the distribution of the Cu₂S fraction among the nanorods. The temporal separation of nucleation and growth stages is often used to achieve monodisperse colloidal nanostructures (Peng, Z. A.; Peng, X. Journal of the American Chemical Society, 124:3343-3353 (2002); Peng et al., Journal of the American Chemical Society, 120:5343-5344 (1998)). In the present case, the present inventors have attempted the rapid addition of the CdS and Cu⁺ solutions or slow injection of Cu⁺ at a constant rate. With further optimization of the rate of Cu⁺ addition throughout the course of the reaction it may be possible to maximize the selectivity for nucleation on the (000 1̅) facet while also separating the nucleation and growth stages to yield a narrow distribution of Cu₂S within the nanorods.

Embodiments of the invention have demonstrated that the crystallographic selectivity for cation exchange to occur at different facets of ionic nanocrystals plays a notable role in determining the morphology of the resulting nanocrystal heterostructures. The preferential nucleation and growth of Cu₂S at the ends of CdS nanorods during Cu⁺ exchange is attributed to the high stability of CdS—Cu₂S interfaces formed at these facets. In comparison, non-selective nucleation in Ag⁺ exchange leads to the formation of multiple Ag₂S regions within the nanorod. The differences between these two systems lie in both the chemical favorability for creating interfacial bonds as well as the elastic distortions between attachments connecting various facets of the two materials. The relative stabilities of the interfaces that were modeled correspond well with the frequency that the corresponding morphologies are observed. In the future, similar modeling of the epitaxy in nanoscale heterostructures may be applied to other material pairs to predict which interfaces will be the most stable. As both the shape and size of the nanocrystals determine the crystallographic facets exposed at the surface, these parameters can be used to control the nanocrystal's reactivity. Selective facet reactivity can in turn provide tunability of the physical properties of nanocrystal heterostructures through control of the spatial arrangement of their components.

Although the foregoing invention has been described in some detail by way of illustration and example for purposes of clarity of understanding, one of skill in the art will appreciate that certain changes and modifications may be practiced within the scope of the appended claims. In addition, each reference provided herein is incorporated by reference in its entirety to the same extent as if each reference was individually incorporated by reference.

What is claimed is:

1. A composite nanorod comprising:
a linear body including three or less alternating regions including a first region and a second region, wherein the first region comprises a first material comprising a first ionic material and the second region comprises a second material comprising a second ionic material.

2. The nanorod of claim 1, wherein the first ionic material and the second ionic material are semiconductors.

3. The nanorod of claim 1, wherein the nanorod has a length less than about 200 nanometers.

4. The nanorod of claim 1, wherein the linear body comprises one first region between two second regions.

5. The nanorod of claim 1 wherein the nanorod comprises a diameter less than about 15 nanometers.

6. The nanorod of claim 1 wherein the first region comprises CdS and the second region comprises Cu₂S.

7. The nanorod of claim 1 wherein the linear body further comprises a third region comprising the second material, wherein the first region is between the second region and the third region.

8. The nanorod of claim 7 wherein the second material comprises copper sulfide and the first region comprises cadmium sulfide.

9. A solar cell device comprising:
a first electrode;
a second electrode; and
at least one nanorod according to claim 1 between the first electrode and the second electrode.

10. A method comprising:
forming a mixture comprising nanorods comprising a first material comprising first ions, coordinating molecules, and second ions in a solvent; and
forming composite nanorods in the solvent, wherein each composite nanorod comprises a linear body comprising a first region comprising the first material and a second region comprising a second material comprising the second ions, wherein the linear body including three or less alternating regions.

11. The method of claim 10 wherein the first material comprises CdS.

12. The method of claim 10 wherein the second material comprises Cu₂S.

13. The method of claim 10 wherein the second material comprises the second ions, wherein the first ions are cadmium ions and the second ions are copper ions.

14. The method of claim 10 wherein the coordinating molecules comprises alcohols.

15. The method of claim 10 wherein the solvent comprises an organic solvent.

16. The method of claim 10 wherein the solvent comprises toluene.

17. The method of claim 10 wherein the linear body further comprises a third region comprising the second material, wherein the first region is between the second region and the third region.

18. The method of claim 17 wherein the second material comprises copper sulfide and the first material comprises cadmium sulfide.

19. A composite nanorod comprising:
a linear body comprising a first region and a second region, wherein the first region comprises a first material comprising cadmium sulfide and the second region comprises a second material comprising copper sulfide.

20. A method comprising:
forming a mixture comprising nanorods comprising a first material comprising first ions, coordinating molecules, and second ions in a solvent; and
forming composite nanorods in the solvent, wherein each composite nanorod comprises a linear body comprising a first region comprising the first material and a second region comprising a second material, wherein the first material comprises cadmium sulfide and the second material comprises copper sulfide.
